(19) United States
(12) Patent Application Publication
(10) Pub. No.: US 2012/0001498 A1
(43) Pub. Date: Jan. 5, 2012

(54) SEQUENTIALLY SWITCHED MULTIPLE PULSE GENERATOR SYSTEM

(76) Inventor: Jonathan R. Mayes, Austin, TX (US)

(21) Appl. No.: 12/829,018

(22) Filed: Jul. 1, 2010

(51) Int. Cl. H03K 3/00

(52) U.S. Cl. 307/106

(57) ABSTRACT

A compact multiple generator system offering high voltage, high repetition rate customizable output waveforms, including rectangular waveforms and variable pulse spacing.

This invention was made with Government support under FA9451-07-C-006 awarded by the United States Air Force. The Government has certain rights in the invention.

### FIELD OF THE INVENTION

The present invention pertains to the field of electronic pulse generation, namely pulsed power sources, and is an improvement over existing Marx generator-type circuits that produce high voltage pulses.

### BACKGROUND OF THE INVENTION

The several variations of a Marx-type generator, commonly known in the electronics industry and herein simply defined and referred to as Marx generator, is a voltage multiplying circuit in which N capacitors are charged, with a power source, in parallel, to an input voltage V_{ch}, after which the charged capacitors are switched into a series configuration so that the output voltage, in a temporary short burst, equals the sum of the voltages across each of the capacitors, or N·V_{ch}. This voltage multiplication enables the designer to achieve extremely high output voltages with a relatively low input voltage power supply.

Each Marx generator stage typically incorporates a switch designed to close at a predetermined voltage. At closure, the capacitor stages add, or, in the commonly understood industry terminology, “erect,” to form an overall capacitance that is equal to the individual stage capacitance divided by the number of stages, and the resultant output voltage is the individual stage voltage multiplied by the number of stages.

The simple Marx generator circuit, schematically depicted in FIG. 1, illustrates a resistively charged circuit, or one in which the stage capacitors, Cₛ=C_{stage} (1), are charged via resistive elements, R_{ch} (3). The stage capacitors 1 are additionally connected via switches S (2), so that with nearly simultaneous closure, the stage capacitors 1 are connected in a series configuration. The circuit is charged by input HV, and the resistive load is denoted by R_{Load}. Thus a single stage may be defined by the stage capacitor 1, two charging resistors 3, and a switch 2. For charge voltages from tens of kilovolts (kV), spark gap switches are employed.

Once erected, the Marx generator dumps its energy into the load, which is resistive, capacitive, inductive, or some combination of the three, such as a lossy transmission line. Assuming a resistive load for simplicity, the voltage pulse delivered by the Marx generator, illustrated in FIG. 2, is characterized by the voltage risetime 4, and a fall (or decay) time 5, referred to as a double exponential. For many applications, this waveform is acceptable. However, for some load applications such as High Power Microwaves, or HPMs, a longer duration peak voltage, as depicted in FIG. 3, is desired. Typical Marx generators provide relatively short duration voltage peaks with undesirably long decay times, whereas the present invention offers customizable output waveforms. The system was first presented by the inventor at the 2009 IEEE Pulsed Power Conference, in Washington, D.C. on Jul. 2, 2009. See Mayes and Hatfield, Development of a Sequentially Switched Marx Generator for HAM Loads, Conference Proceedings of the 2009 IEEE Pulsed Power Conference.

Several geometries employ Marx generators as base devices for Pulse Forming Networks (PFNs). In a published patent application (US 2008/0036301 A1), McDonald offers a good summary of common Marx generator-based PFN geometries, but merely describes and claims switching with photon-initiated semiconductors instead of spark gap switches.

Illustrated in FIG. 4, a Marx generator 6 is loaded by series LC tank circuits 7, which are included to shape the double exponential waveform of FIG. 2 into the rectangular shape of FIG. 3. This technique is described by McDonald in his 2008 publication, and reported by Mayes in a report to the Ballistic Missile Defense Organization, under U.S. Army contract DASG60-00-M-0082. This geometry is commonly referred to as a Type A PFN, utilizing a Marx generator with a single capacitor 8 and a single inductor 9. Several, similar geometries employ Marx generators as base devices for Pulse Forming Networks (PFNs).

Another technique replaces the simple capacitors of the Marx generator of FIG. 1 with transmission lines 10, shown in FIG. 5. This technique was first used at Sandia National Laboratory, and revisited by McDonald supra. In such geometry the transmission lines 10 are momentarily added in a manner identical to the manner in which Marx generator stages are added. However, instead of the capacitive discharge, the stacked transmission lines simultaneously release their energy, and the result is a rectangular shape having an amplitude similar to the added voltages of the transmission lines. This technique was reported by Mayes to the Defense Advanced Research Projects Agency (DARPA), in April 2002, in a final report titled “A Compact Quantum Pulse Power Module”, under DARPA/CMO contract #MDA972-01-C-0014.

Another geometry uses multiple Marx generators within a PFN. As shown in FIG. 6, several parallel Marx generators 11 are connected via series inductors 12 in a geometry commonly referred to as a Type E PFN network.

### SUMMARY OF THE INVENTION

One objective of this present invention is the provision of a Marx-type high voltage generator that delivers a rectangular-shaped voltage pulse.

A further objective of the present invention is the provision of a very compact generator.

A further objective of the present invention is the provision of a Marx-type generator capable of highly flexible delivery of unique pulse shapes and load interactions.

A further objective is a system in which the failure of an individual generator does not cause overall system failure.

In the preferred embodiment, multiple commonly-housed Marx generators share a common output connection and are sequentially switched so that energy from each generator is uniquely or individually delivered to the common output. In the fundamental process, the generators sequentially deliver their respective energy pulses with short time delays between pulses. However, the geometry naturally lends itself to custom temporal spacing, since each generator is individually triggered by any number of various triggering, devices commonly known in the industry. See, for example, Mayes et al. (U.S. Pat. No. 7,741,735 B2).

One advantage of the present invention is the use of multiple Marx generators sequentially delivering energy to a common load so that a rectangular voltage pulse is realized. The geometry of the present invention leads to a very compact configuration.

An additional advantage of the present invention is the graceful failure of the device. Each Marx generator can be individually charged and controlled. If an individual Marx generator fails, the remaining generators may continue to function with a somewhat reduced width in the delivered rectangular voltage pulse.

An additional advantage of the present invention is the ability to generate alternate waveforms. Since each Marx generator can be individually and uniquely charged and controlled, each generator can deliver variable amplitudes. Furthermore, each generator can be controlled to deliver its energy at any unique, selectable time.

The impedance of each Marx generator is matched to the load impedance. Each Marx generator is inductively isolated from the load, either with an inductor or through geometric inductance such that no generator is affected by operation of any neighboring generator. The Marx generators are housed in a common metal vessel.

The Marx generators can either share a common power supply, or each can be uniquely charged with an independent power supply. The Marx generators can be sequentially triggered from a common trigger circuit and unique trigger delay lines between each generator and the trigger circuit. Alternatively, the Marx generators can be triggered by independent trigger circuits.

### BRIEF DESCRIPTION OF THE DRAWINGS

FIG. 1 is a schematic of the simple Marx generator circuit.

FIG. 2 depicts a Gaussian-like, or double exponential pulse shape.

FIG. 3 depicts a rectangular-shaped pulse.

FIG. 4 is a schematic of a Type A pulse forming network-based Marx generator circuit.

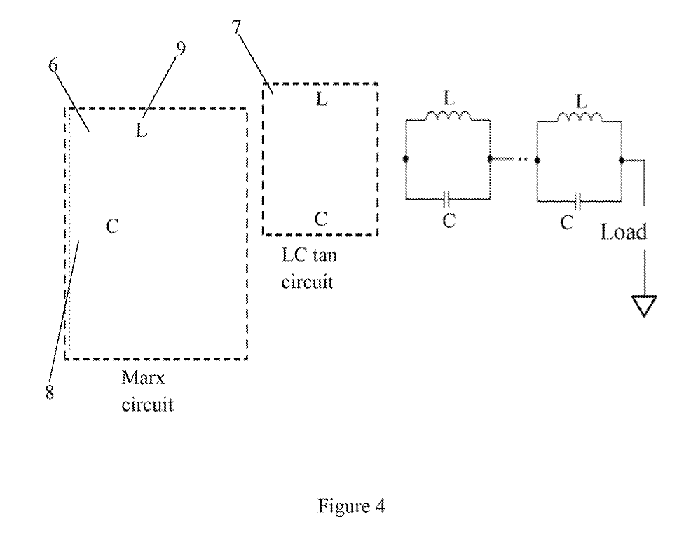

FIG. 5 is a schematic of a transmission line-based Marx generator.

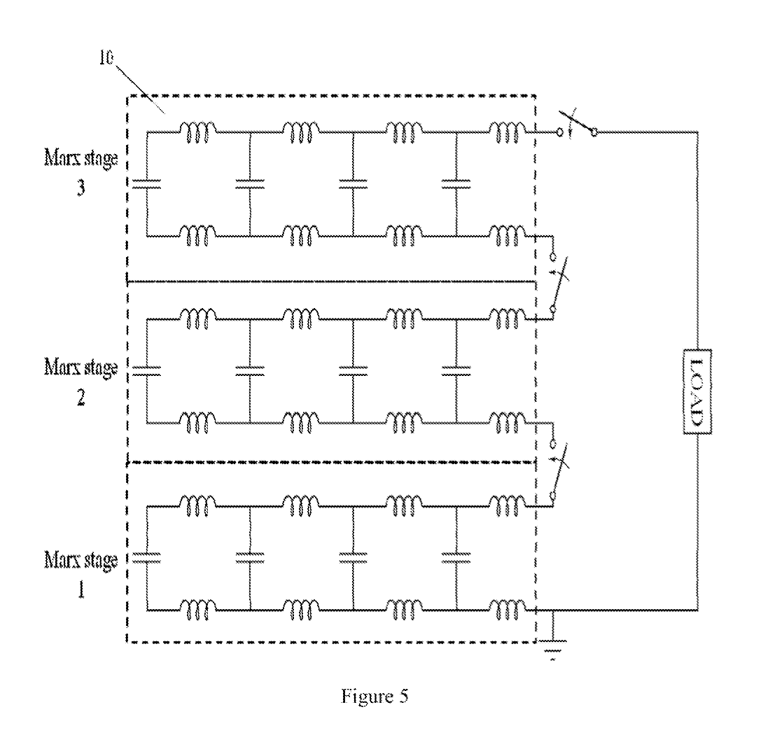

FIG. 6 is a schematic of a Type E pulse forming network-based Marx generator circuit.

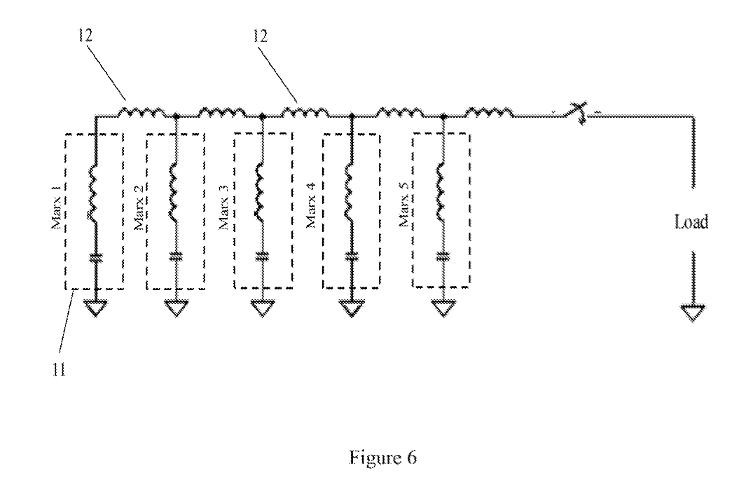

FIG. 7 depicts the formation of a rectangular-shaped pulse using a closely-spaced sequence of Gaussian pulses.

FIG. 8 depicts a distorted waveform in which the Gaussian-like pulses are too closely spaced.

FIG. 9 depicts a rectangular waveform with substantial ripple due to the Gaussian-like pulses being delivered too far apart.

FIG. 10 is a schematic describing the present invention, in which multiple Marx generator-like circuits are individually charged and triggered to deliver unique waveforms and pulse delivery times to a common load.

FIG. 11 depicts a synthesized sine wave from the present invention using dual polarity Marx generator-like circuits.

FIG. 12 depicts a synthesized sine wave from the present invention using the ability to charge the individual sub-Marx generators to different voltage levels.

FIG. 13 depicts a pulse-coded waveform in which a burst of eight pulses is delivered. However, several pulses are selected to not be delivered so as to form a binary code.

FIG. 14 depicts the present invention configured to deliver closely spaced pulses from the sub-Marx generators to form bursts of pulses at high repetition rates.

FIG. 15 depicts the present invention configured to deliver equi-spaced pulses from the sub-Marx generators.

FIG. 16 depicts the present invention operating with variable temporal spacing between the pulses from the sub-Marx generators.

FIG. 17 is a schematic for the single-point triggering method, utilizing a single trigger switch connected to the sub-Marx generators with unique, various-length connecting cables.

FIG. 18 depicts the housing structure for the present invention.

FIG. 19 depicts a cross sectional view of the internal structure, illustrating the plastic insulator and the radial placed sub-Marx generators.

FIG. 20 depicts the present invention built with individually-packaged sub-Marx generators that may individually be removed from the housing.

FIG. 21 depicts a Marx generator-circuit stage platter containing a capacitor, a spark gap, and the charge elements for one sub-Marx generator.

FIG. 22 depicts the air handling for each platter.

FIG. 23 depicts the construction of a platter capturing the key Marx generator circuit components for a single Marx generator stage.

FIG. 24 depicts an assembled platter, or module, and illustrating the electrical connections between neighboring modules.

FIG. 25 depicts the stacking of modules.

FIG. 26 depicts the output of the preferred invention, including the tailbiter circuit and saturable inductors which provide sub-Marx generators with isolation.

### DETAILED DESCRIPTION OF THE PREFERRED EMBODIMENT

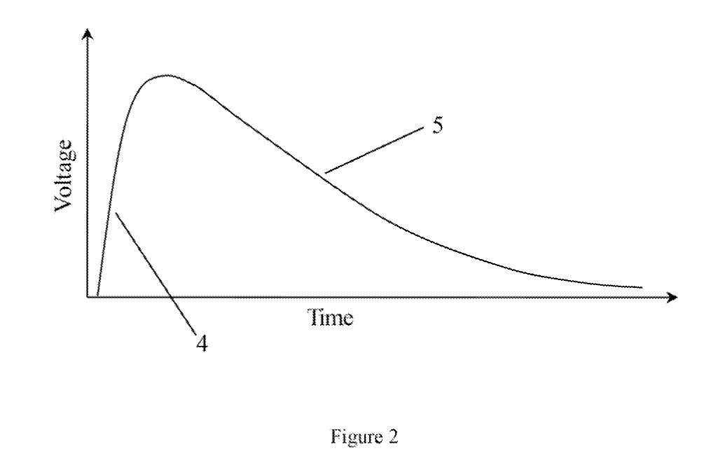

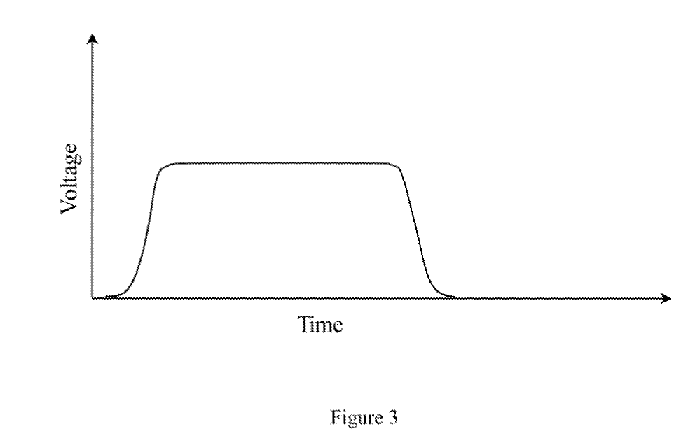

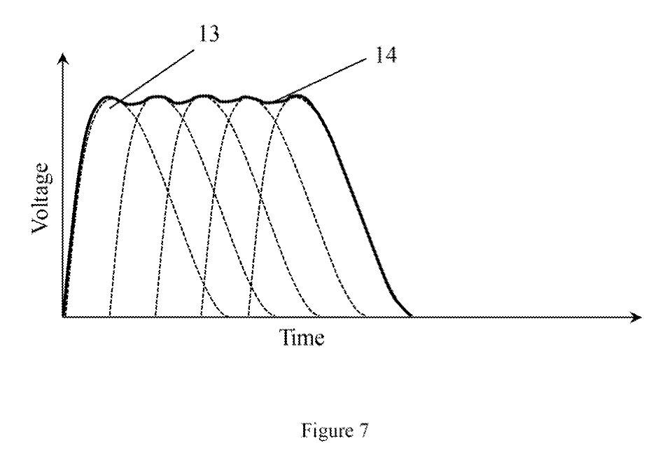

A rectangular voltage pulse as in FIG. 3 can be constructed from the sequential delivery of short duration Gaussian-like pulses like the ones depicted in FIG. 2. As shown in FIG. 7, closely spaced pulses 13 can produce a substantially rectangular waveform 14. With careful design, the capacitance of the load will integrate, or smooth the waveform to more closely approximate the rectangular waveform. To achieve high voltage levels, Marx generators are used to generate the short duration pulses, and multiple Marx generators can be sequentially triggered to deliver the closely spaced Gaussian-like pulses 13.

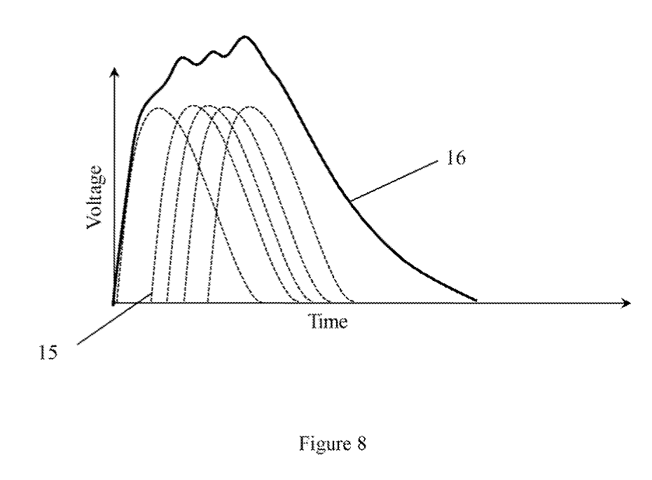

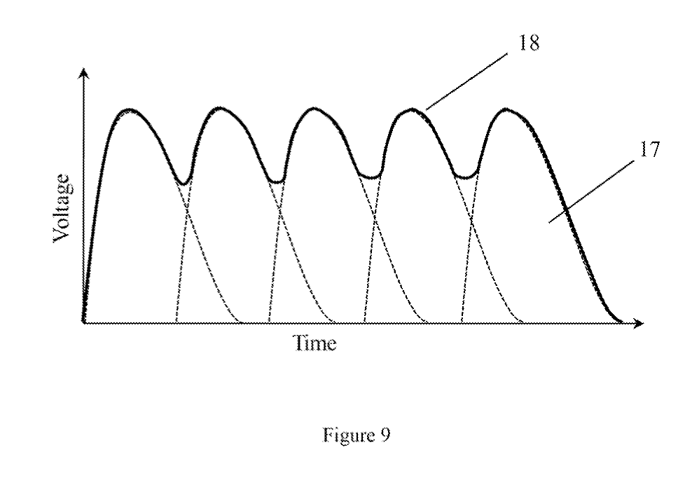

The timing of the pulse arrival at the load is not necessarily critical; however, the timing does affect the amount of ripple and distortion that will be seen on the flattop portion of the waveform. Gaussian-like pulses 15 delivered too closely will result in more dramatic peaks in the pulse 16 delivered to the load, as illustrated in FIG. 8; and Gaussian-like pulses 17 delivered with too much separation will result in more dramatic valleys in the pulse 18 delivered to the load, as illustrated in FIG. 9. By carefully tuning the delivery time of each pulse, the ripple of the rectangular pulse can be minimized.

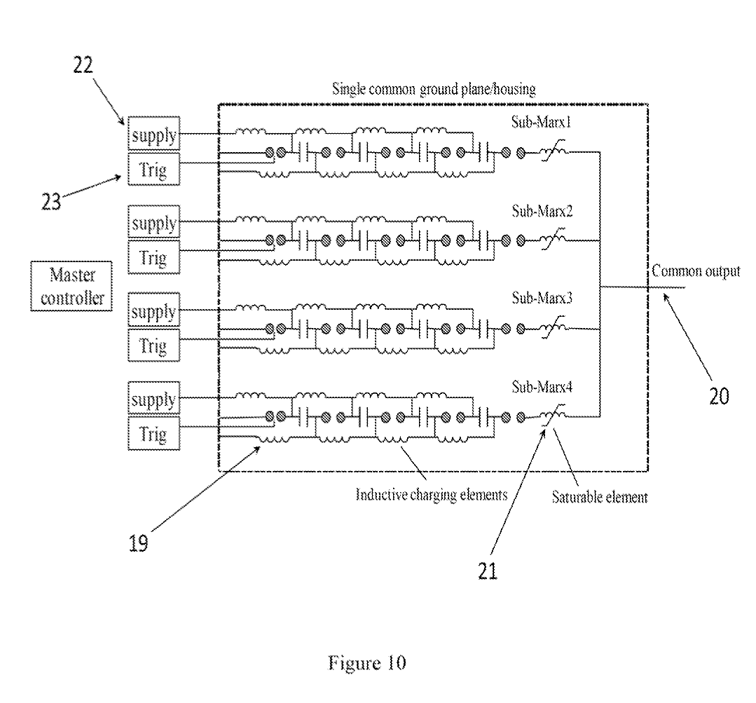

The schematic of FIG. 10 provides a simple circuit description of the present invention. In general, multiple Marx generators 19, each now referred to now as “sub-Marx” generators, are placed in a parallel configuration and connected to a common output load 20. Between each sub-Marx generator 19 and the common load connection 20 should be an inductive isolation element 21 that protects each sub-Marx generator 19 from neighboring sub-Marx generator effects such as pre-triggering.

The preferred embodiment of this invention powers each sub-Marx generator 19 with an individual power supply 22 and triggers each sub-Marx generator with an individual trigger unit 23. There are several advantages of providing each sub-Marx generator with its own power supply and trigger source—namely, graceful failure of the system, unique waveform generation, and source impedance flexibility.

Graceful failure is a unique concept to pulse power systems, since typical pulse power systems cease to function with the failure of any single component. In the present invention the pulse power system is comprised of multiple sub-Marx generators, each operating autonomously, and thus, operating with redundancy. Thus, if one sub-Marx generator fails, it does not bring the whole system down. Instead, the system continues operating with one less sub-Marx generator.

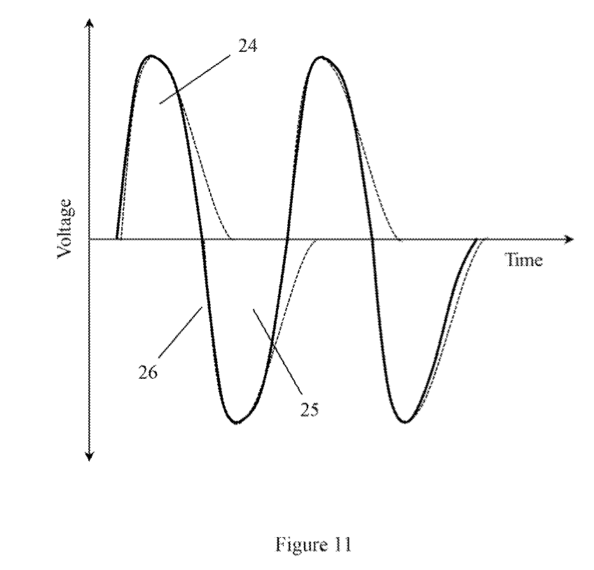

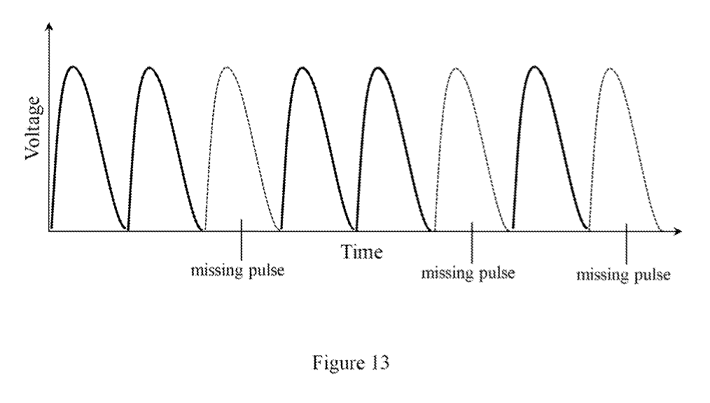

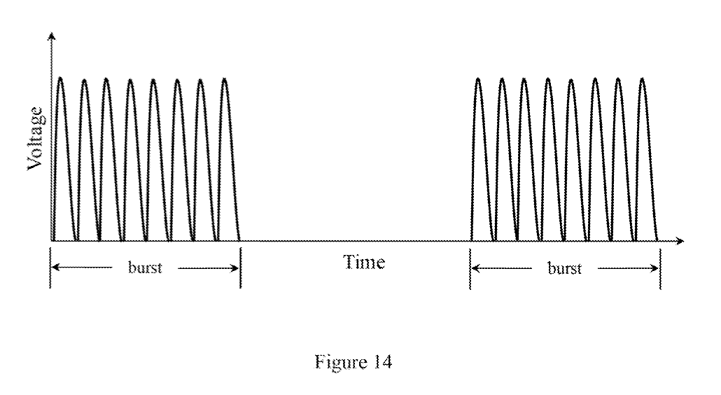

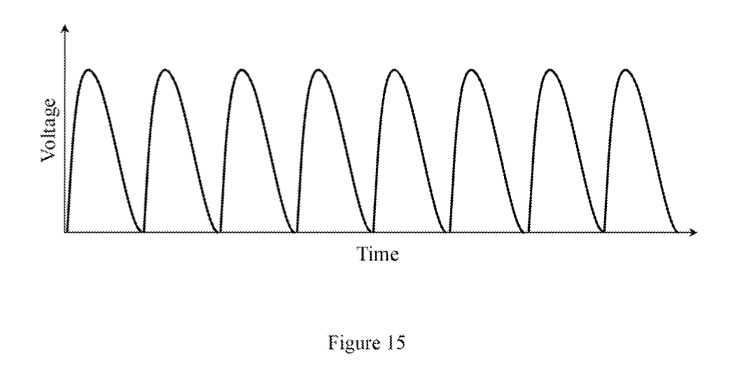

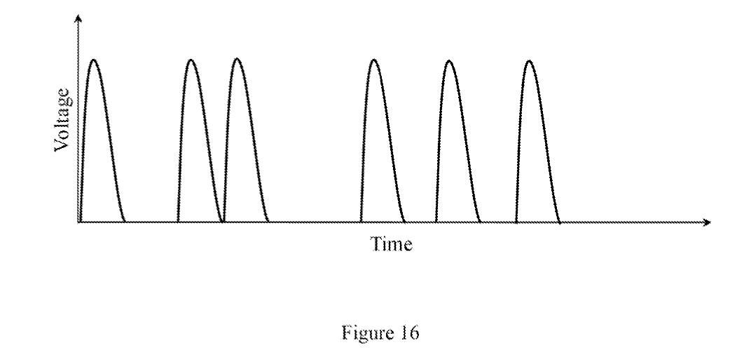

Since each sub-Marx generator is charged and triggered independently of neighboring sub-Marx generators, output waveform, spacing, and timing flexibility are inherent. In general, each sub-Marx generator can be charged to deliver a wide range of voltages of positive or negative polarity. Each sub-Marx generator can be triggered to deliver energy at any point in time, or it can be selectively silenced. Non-exclusive system variability can include, but is not limited to the example waveforms depicted in FIGS. 11-16.

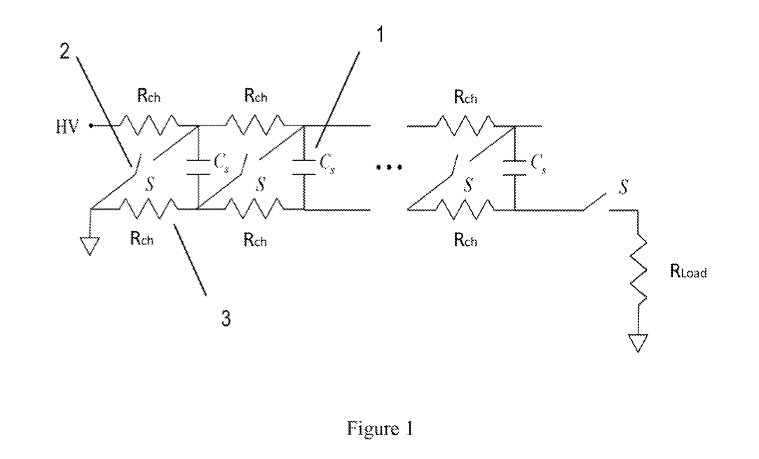

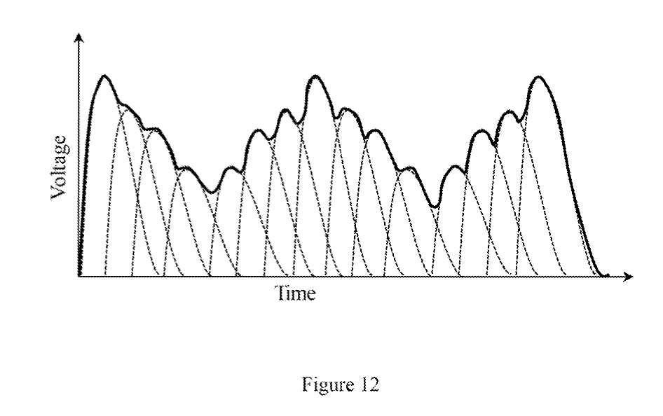

FIG. 1I depicts closely-space bipolar pulses, or a positive polarity Gaussian-like pulse 24 followed by a negative polarity Gaussian-like pulse 25 that together simulate a sine wave 26. The bipolar pulses are achieved using dual polarity charging power supplies. FIG. 12 demonstrates the invention's capability to vary the magnitude of the charge voltage on each sub

Another advantage provided by the individual triggering feature of this invention is impedance matching. A system designed for use with a certain impedance load has the flexibility to be used with loads of various other impedances. The individual sub-Marx generators can all be constructed with identical or different impedances, and those various impedances can be selectively combined for a desired output impedance through the selective triggering capability of this invention.

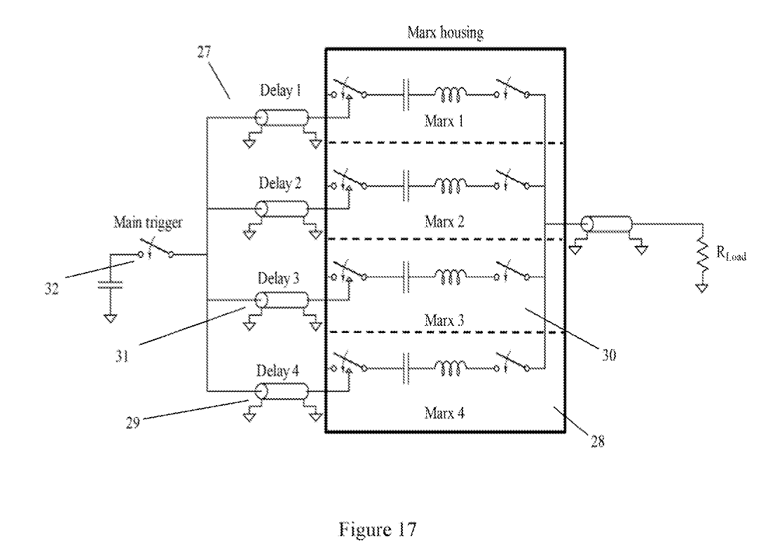

The pulse power system of this invention may also rely on a single power supply and a single triggering unit. A single power supply is simply connected to the parallel sub-Marx generators. However, such an embodiment lacks the capability to charge the sub-Marx generators with different voltage levels. Similarly, a single trigger unit may be used to trigger the multiple sub-Marx generators. However, as depicted in FIG. 17, sequential generator triggering requires that the trigger connections for the individual sub-Marx generators 28 (Marx 1, 2, 3, and 4) have unique predetermined electrical transmission properties. For example, the lengths of the trigger connection cables that connect each sub-Marx generator to the main trigger switch 32 can be chosen for provision of a desired trigger delay time for each sub-Marx generator. Marx 1 generator might be triggered at 10 ns, with trigger cable 27 having an approximate length of 2.5 m. Marx 3 might have a trigger cable 31 approximately 11.7 in long

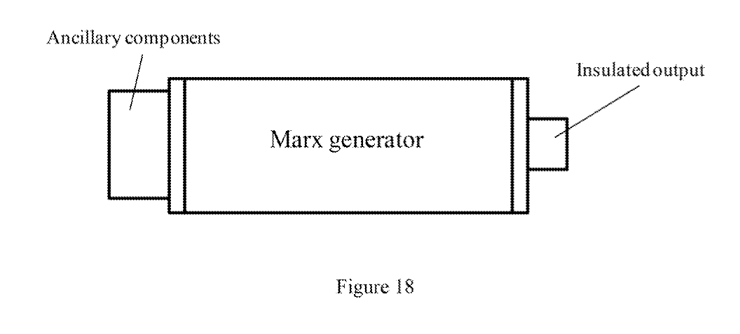

The preferred embodiment of this invention localizes the sub-Marx generators into a common conductive housing structure, as shown in FIG. 18. Ancillary components such as a power supply, or power supplies, and the triggering unit, or triggering units, are located in a separate but connected conductive housing. This configuration minimizes the volume required for the system.

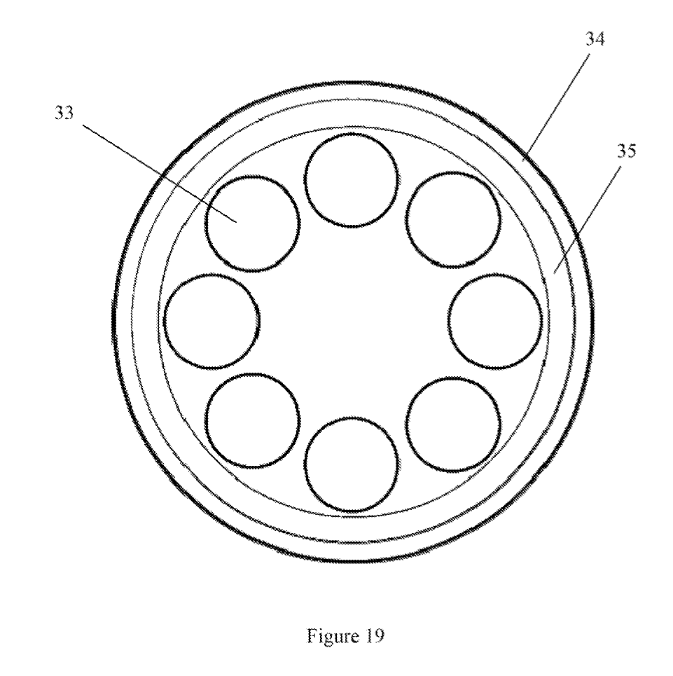

The sub-Marx generators 33 housed in a common containment structure are radially located inside the cylindrical housing 34, shown in FIG. 19. The preferred embodiment lines the inside of the cylinder with a plastic material 35 to prevent the sub-Marx generators 33 from arcing to the cylinder 34, thus short circuiting the Marx generator circuit. The plastic material 35 is preferred over air insulation, so that the sub-Marx generator 33 can be located very close to the ground potential provided by the electrically conductive cylinder 34. Such grounding is referred to as capacitive coupling to the ground potential.

Capacitive coupling the sub-Marx generators to the ground potential is an important feature of the present invention system. Without a strong reference to the ground potential, triggering any sub-Marx generator can cause all of the other sub-Marx generators to self-trigger. However, with a good reference to the ground potential, self-triggering of sub-Marx generators can be avoided.

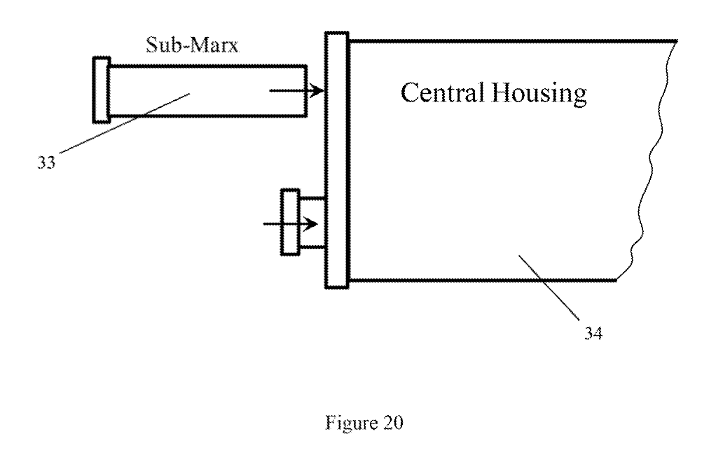

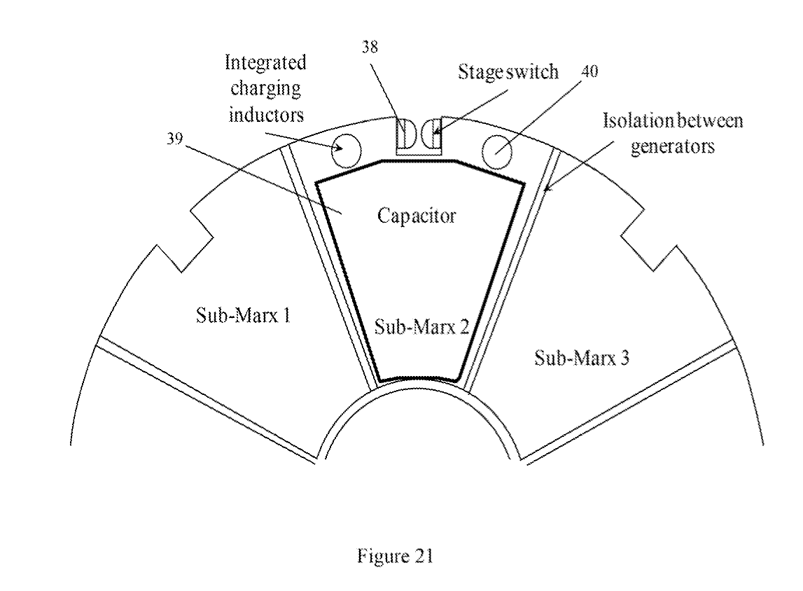

The sub-Marx generators 33 can be individually packaged, so that each sub-Marx generator 33 can be individually removed from the central housing 34, as depicted in FIG. 20. The geometry of this alternate embodiment provides for easy construction and maintenance. However, the preferred embodiment of this invention integrates like stages of each sub-Marx generator into a single disc-like structure, or platter. This embodiment provides for a geometry much more compact than that of the FIG. 20 embodiment. For example, a system of 8 sub-Marx generators, each comprised of 20 Marx generator stages, would consist of 20 platters, with each platter holding one stage for each of the 8 sub-Marx generators, including the spark gap 38, the stage capacitor 39, and the charging elements 40, as depicted in FIG. 21. The stage platters stack vertically to complete the cylindrical system package.

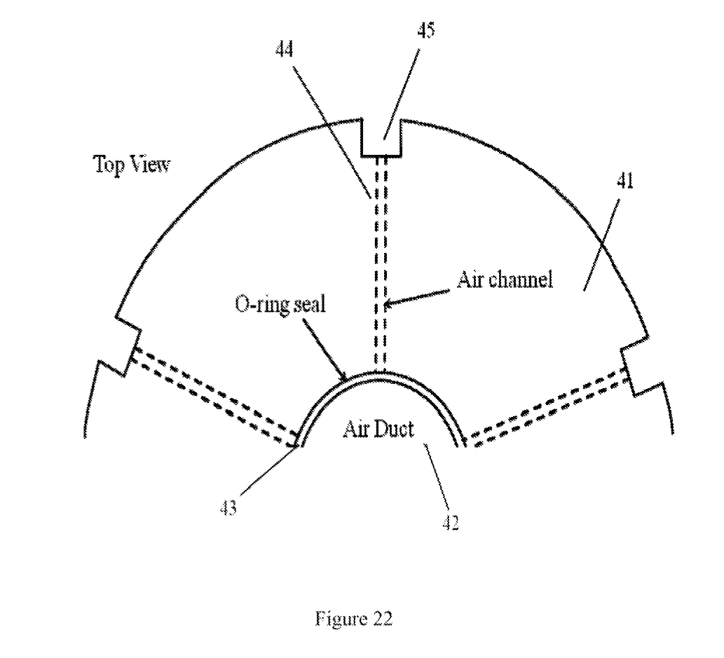

Since the sub-Marx generators are located radially near the cylindrical housing structure, the central area of each platter 41 is available and used as a central air duct 42. As depicted in FIG. 22, material is removed from this region and o-ring seals 43 are located so that air does not escape from between the stage platters 41. For each stage platter 41, small holes 44 are drilled from the central duct 42 to each spark gap switch region 45, so that during the operation of the system, fresh air flows into the spark gap region 45.

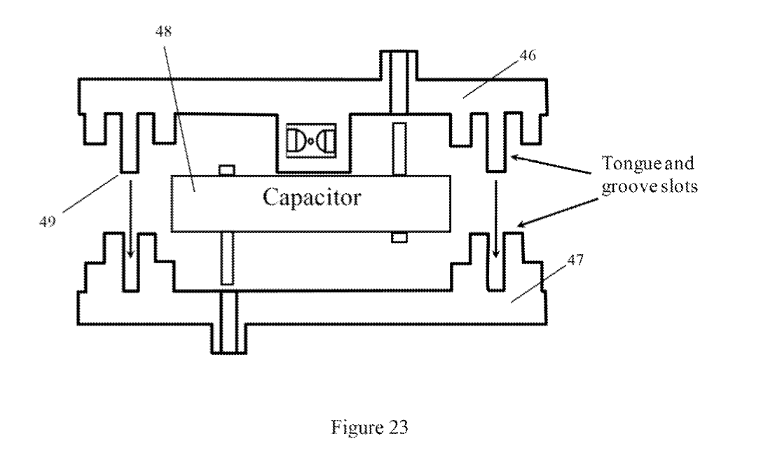

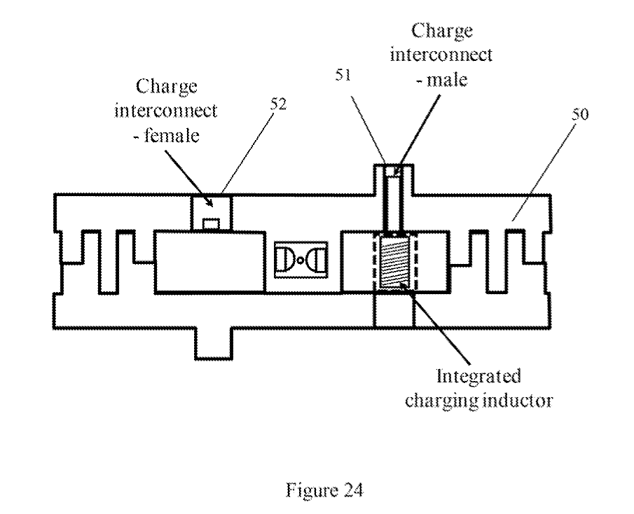

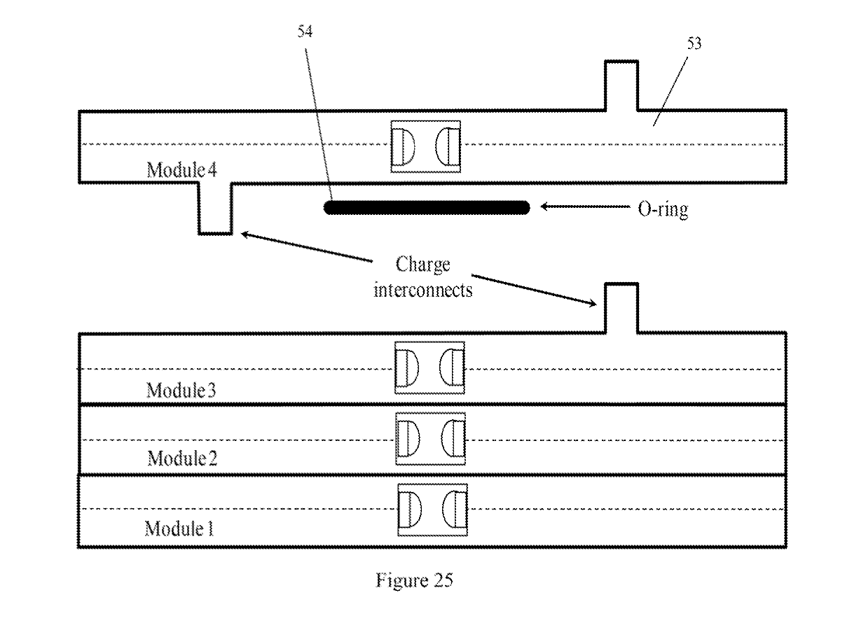

The side view of the pre-assembled stage insulator is shown in FIG. 23. Two machined ABS discs, a top plate 46 and a bottom plate 47, encompass the parallel sub-Marx generator stage capacitors 48. “Tongue and groove” slots 49 are designed to ensure electrical isolation between neighboring sub-Marx generators. FIG. 24 is a side view of the stage insulator assembly 50 showing insulated stage charge interconnections. Male charge connections 51 connect to the female charge connections 52 of the adjacent (next-in-line) Marx generator stage. FIG. 25 depicts several platter assemblies, or modules 53, stacked together, with o-rings 54 between each platter for sealing of the central air duct.

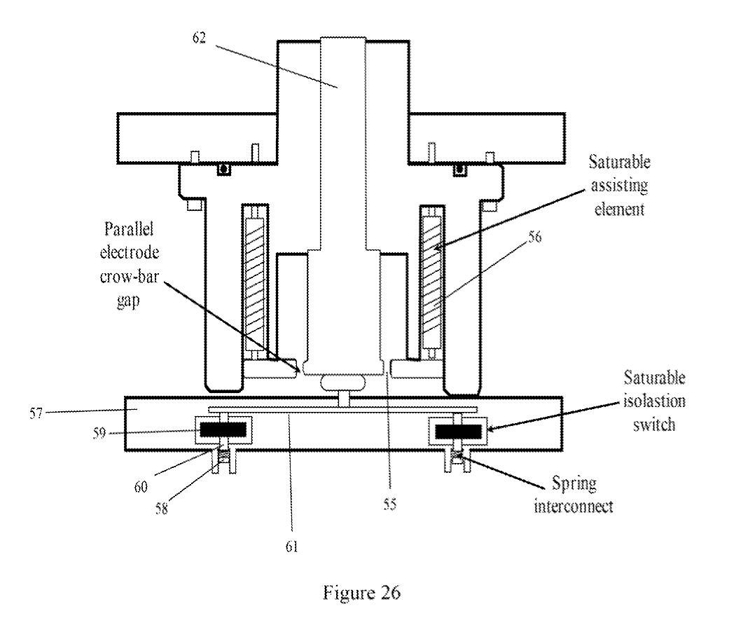

The output section is defined by two key components—the isolation platter and the tailbiter, or crowbar switch. Shown in FIG. 26, the isolation platter encases the isolation inductors in a manner similar to that in which the generators are encased. The isolation platter makes the common electrical connection between the sub-Marx generators, before making contact with the output-feed through.

The output feed-through is designed with a tailbiter circuit including an integrated crowbar switch, which is included to produce a more dramatic fall time on the output voltage pulse. The crowbar switch should have extremely low inductance. The preferred embodiment, shown in FIG. 26, uses a spark gap switch 55, aided with a saturable inductor 56. In this configuration most of the voltage drop will be realized across the inductor 56; however, once the inductor 56 saturates, the spark gap 55 will be over-voltaged and will close, thus short circuiting the system and extinguishing the voltage on the load. Alternatively, a single magnetic saturable switch can be designed to shunt the voltage at the appropriate time. Either method will quench the trailing voltage tail of a rectangular pulse.

Each sub-Marx generator connects to the final platter 57 via a spring interconnection 58. A small saturable ring 59, such as a ferrite torroid, is placed around the electrical feed 60 to provide some isolation from neighboring sub-Marx generators. On the output side of each saturable element 59, a common plate 61 connects all sub-Marx generators to the common output feed 62.

I claim:

1. A pulse-generating system comprising a plurality of Marx generators dumping their respective individual energy output pulses into a common output connection, said generators being sequentially triggered via at least one trigger connection.

2. A system as in claim 1 wherein at least one of said generators is independently triggered by a dedicated trigger.

3. A system as in claim 1 wherein two or more said generators are substantially simultaneously triggered by a dedicated trigger.

4. A system as in claim 1 wherein electrical transmission properties of all said trigger connections are substantially equivalent.

5. A system as in claim 1 wherein electrical transmission properties of said trigger connections are tailored for various predetermined trigger times.

6. A system as in claim 1 wherein all said generators are powered by a common supply.

7. A system as in claim 1 wherein at least one said generator is powered independently by a dedicated supply.

8. A system as in claim 1 wherein two or more said generators are powered simultaneously by a dedicated supply.

9. A system as in claim 1 wherein said generators are powered with supply levels not all of which are equal.

10. A system as in claim 1 wherein said generators in predetermined sequence dump said pulses with predetermined frequencies into a common output connection.

11. A system as in claim 1 wherein said generators in predetermined sequence dump said pulses into a common output connection in bursts of predetermined duration.

12. A system as in claim 1 wherein said generators in predetermined sequence dump said pulses into a common output connection in bursts having predetermined, variable temporal spacing.

13. A system as in claim 1 wherein said pulses combine to form a substantially rectangular waveform at said common output connection.

14. A system as in claim 13 further comprising circuitry that quenches the trailing voltage tail of said waveform.

15. A system as in claim 1 wherein said pulses combine to form a predetermined variable waveform at said common output connection.

16. A system as in claim 1 wherein one or more said generators are selectively triggered to provide a predetermined combined output impedance.

17. A system as in claim 1 wherein each said generator is individually removable from said system.

18. A system as in claim 1 further comprising an electrically conductive enclosure in which all said generators are housed.

19. A system as in claim 18 wherein all said generators are housed proximate to said enclosure.

20. A system as in claim 1 wherein said generators comprise stacked platters, each said platter comprising one stage for each said generator.

21. A system as in claim 20 wherein one or more said platters further comprise air ducts.

22. A system as in claim 20 wherein one or more said platters further comprise air sealing elements.

23. A system as in claim 20 wherein one or more said platters further comprise electrical isolators.

24. A system as in claim 20 wherein one or more said platters further comprise electrical feedthrough connections that upon assembly of said system communicate with corresponding electrical connections in adjacent platters.
